(19) United States
(12) Patent Application Publication
(10) Pub. No.: US 2024/0155903 A1
(43) Pub. Date: May 9, 2024

(54) DISPLAY DEVICE AND MANUFACTURING METHOD OF THE SAME

(71) Applicant: Japan Display Inc., Tokyo (JP)

(72) Inventor: Sho YANAGISAWA, Tokyo (JP)

(73) Assignee: Japan Display Inc., Tokyo (JP)

(21) Appl. No.: 18/498,118

(22) Filed: Oct. 31, 2023

(30) Foreign Application Priority Data
Nov. 7, 2022 (JP) 2022-178253

(51) Int. Cl. H10K 59/131; H10K 59/12; H10K 59/121; H10K 59/88

(52) U.S. Cl. CPC H10K 59/1315; H10K 59/1201; H10K 59/1213; H10K 59/88

(57) ABSTRACT

A display device according to an embodiment of the present invention includes a substrate, a display part including a plurality of pixels, each of which includes a transistor having an oxide semiconductor layer on the substrate, a first wiring electrically connected to the plurality of pixels, a terminal electrically connected to the first wiring, and a second wiring which is an oxide conductive layer having the same composition as the oxide semiconductor layer, has a cross-sectional surface along a periphery of the substrate, and is electrically connected to the terminal.

### CROSS-REFERENCE TO RELATED APPLICATION

This application claims the benefit of priority to Japanese Patent Application No. 2022-178253 filed on Nov. 7, 2022, the entire contents of which are incorporated herein by reference.

### FIELD

An embodiment of the present invention relates to a display device and a method for manufacturing the display device.

### BACKGROUND

A display device using an element, a liquid crystal element or the like utilizing organic electroluminescence (EL) for a display region has, for example, a configuration in which a display part and a plurality of terminals are arranged in a substrate. The plurality of terminals is electrically connected to pixels of the display region, and various signals (for example, an image signal or a control signal) or power supply potentials are input thereto. In order to prevent the electrostatic breakdown of an electronic component during the manufacturing of the display device, a short-circuit wiring (short ring) for short-circuiting the plurality of terminals may be arranged (for example, Japanese laid-open patent publication No. 2016-42130). The short ring is removed from the display device before shipping.

In the conventional short-circuit wiring, polysilicon, metal or the like to which impurities are added has been used. A short-circuit wiring using polysilicon has a high wiring resistance and is difficult to inspect for electric properties in a manufacturing process of the display device. In addition, although the wiring resistance of the short ring using metal is low, a cross-sectional surface of the wiring is exposed due to cutting before shipping, the cross-sectional surface comes into contact with moisture or the like, and corrosion is likely to occur.

An object of an embodiment of the present invention is to provide a display device with less defects and suppressed deterioration. Another object of an embodiment of the present invention is to provide a method for manufacturing the display device.

### SUMMARY

A display device according to an embodiment of the present invention includes a substrate, a display part including a plurality of pixels, each of which includes a transistor having an oxide semiconductor layer on the substrate, a first wiring electrically connected to the plurality of pixels, a terminal electrically connected to the first wiring, and a second wiring which is an oxide conductive layer having the same composition as the oxide semiconductor layer, has a cross-sectional surface along a periphery of the substrate, and is electrically connected to the terminal.

A method for manufacturing a display device according to an embodiment of the present invention includes the steps of forming an oxide semiconductor layer of a transistor arranged in each of a plurality of pixels constituting a display part on a substrate, and a first wiring which is an oxide conductive layer having the same composition as the oxide semiconductor layer, forming a first insulating layer over the oxide semiconductor layer and the first wiring, forming a gate electrode of the transistor and a second wiring electrically connected to the first wiring over the first insulating layer, and forming a second insulating layer over the gate electrode and the second wiring, forming a plurality of first openings reaching the first wiring and second openings reaching the second wiring in the second insulating layer, forming a third wiring electrically connected to the second wiring over the second insulating layer and in the plurality of first openings and the plurality of second openings, forming a third insulating layer over the third wiring, forming a test pad and a terminal electrically connected to the second wiring on the third insulating layer, and cutting the substrate so that the first wiring is divided.

A method for manufacturing a display device according to an embodiment of the present invention includes the steps of forming a first wiring and a gate electrode of a transistor arranged in each of a plurality of pixels constituting a display part on a substrate, forming a first insulating layer over the first wiring and the gate electrode, forming an oxide semiconductor layer of the transistor over the first insulating layer and a second wiring which is an oxide conductive layer having the same composition as the oxide semiconductor layer and electrically connected to the first wiring, forming a plurality of openings reaching the first wiring in the first insulating layer, forming a third wiring over the second wiring and in the plurality of openings, forming a second insulating layer over the third wiring, forming a test pad and a terminal electrically connected to the first wiring over the second insulating layer, and cutting the substrate so that the second wiring is divided.

### BRIEF DESCRIPTION OF DRAWINGS

FIG. 1 is a top view showing a configuration of a display device according to an embodiment of the present invention.

FIG. 2A is a diagram showing a configuration of a pixel circuit of a display device according to an embodiment of the present invention.

FIG. 2B is a diagram showing a configuration of a pixel circuit of a display device according to an embodiment of the present invention.

FIG. 3 is a top view showing a configuration of a display device during manufacturing according to an embodiment of the present invention.

FIG. 4 is a top view showing a terminal of a display device and its periphery during manufacturing according to an embodiment of the present invention.

FIG. 5 is an end view showing a terminal of a display device and its periphery during manufacturing according to an embodiment of the present invention.

FIG. 6A is an end view showing a configuration of a display device according to an embodiment of the present invention.

FIG. 6B is a diagram illustrating a method for manufacturing a display device according to an embodiment of the present invention.

FIG. 6C is a diagram illustrating a method for manufacturing a display device according to an embodiment of the present invention.

FIG. 6D is a diagram illustrating a method for manufacturing a display device according to an embodiment of the present invention.

FIG. 6E is a diagram illustrating a method for manufacturing a display device according to an embodiment of the present invention.

FIG. 6F is a diagram illustrating a method for manufacturing a display device according to an embodiment of the present invention.

FIG. 6G is a diagram illustrating a method for manufacturing a display device according to an embodiment of the present invention.

FIG. 6H is a diagram illustrating a method for manufacturing a display device according to an embodiment of the present invention.

FIG. 6I is a diagram illustrating a method for manufacturing a display device according to an embodiment of the present invention.

FIG. 6J is a diagram illustrating a method for manufacturing a display device according to an embodiment of the present invention.

FIG. 6K is a diagram illustrating a method for manufacturing a display device according to an embodiment of the present invention.

FIG. 6L is a diagram illustrating a method for manufacturing a display device according to an embodiment of the present invention.

FIG. 7A is a top view showing a terminal of a display device and its periphery during manufacturing according to an embodiment of the present invention.

FIG. 7B is an end view showing a terminal of a display device and its periphery during manufacturing according to an embodiment of the present invention.

FIG. 8A is a top view showing a terminal of a display device and its periphery during manufacturing according to an embodiment of the present invention.

FIG. 8B is an end view showing a terminal of a display device and its periphery during manufacturing according to an embodiment of the present invention.

FIG. 9A is an end view showing a configuration of a display device according to an embodiment of the present invention.

FIG. 9B is a diagram illustrating a method for manufacturing a display device according to an embodiment of the present invention.

FIG. 9C is a diagram illustrating a method for manufacturing a display device according to an embodiment of the present invention.

FIG. 9D is a diagram illustrating a method for manufacturing a display device according to an embodiment of the present invention.

FIG. 9E is a diagram illustrating a method for manufacturing a display device according to an embodiment of the present invention.

FIG. 9F is a diagram illustrating a method for manufacturing a display device according to an embodiment of the present invention.

FIG. 9G is a diagram illustrating a method for manufacturing a display device according to an embodiment of the present invention.

FIG. 9H is a diagram illustrating a method for manufacturing a display device according to an embodiment of the present invention.

FIG. 10A is a top view showing a terminal of a display device and its periphery during manufacturing according to an embodiment of the present invention.

FIG. 10B is an end view showing a terminal of a display device and its periphery during manufacturing according to an embodiment of the present invention.

FIG. 11A is a top view showing a terminal of a display device and its periphery during manufacturing according to an embodiment of the present invention.

FIG. 11B is an end view showing a terminal of a display device and its periphery during manufacturing according to an embodiment of the present invention.

FIG. 12A is a top view showing a terminal of a display device and its periphery during manufacturing according to an embodiment of the present invention.

FIG. 12B is an end view showing a terminal of a display device and its periphery during manufacturing according to an embodiment of the present invention.

### DESCRIPTION OF EMBODIMENTS

Hereinafter, each embodiment of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings, the width, the layer thickness, the shape, and the like of each part may be schematically represented in comparison with an actual embodiment. However, the illustrated shapes are merely examples, and do not limit the interpretation of the present invention. In the present specification and the drawings, the same reference signs are given to elements similar to those described previously with respect to the above-described drawings, and a detailed description thereof may be omitted as appropriate.

A “semiconductor device” refers to any device that can function by utilizing semiconductor properties. A transistor and a semiconductor circuit are one form of the semiconductor device. For example, the semiconductor device may be an integrated circuit (IC) such as a display device or a micro-processing unit (MPU), or a transistor used in a memory circuit.

The “display device” refers to a structure that displays an image using an electro-optic layer. For example, the term display device may refer to a display panel including the electro-optic layer, or may refer to a structure with other optical members (for example, a polarizing member, a backlight, a touch panel, and the like) attached to a display cell. The “electro-optic layer” may include a liquid crystal layer, an electroluminescence (EL) layer, an electrochromic (EC) layer, or an electrophoretic layer, as long as there is no technical contradiction. Therefore, although the display device according to the embodiment described later will be described by exemplifying a liquid crystal display device including a liquid crystal layer and an organic EL display device including an organic EL layer, the structure according to the present embodiment can be applied to a display device including other electro-optic layers described above.

In each embodiment of the present invention, a direction from a substrate toward an oxide semiconductor layer is referred to as “on” or “above”. Conversely, a direction from the oxide semiconductor layer toward the substrate is referred to as “under” or “below”. In this way, for convenience of explanation, although the phrase “above” or “below” is used to for the purpose of description, for example, the upper and lower relationship between the substrate and the oxide semiconductor layer may be arranged so as to be opposite to those shown in the drawings. In the following explanation, for example, the expression “an oxide semiconductor layer on a substrate” merely describes the upper and lower relationship between the substrate and the oxide semiconductor layer as described above, and another member may be arranged between the substrate and the oxide semiconductor layer. The terms “above” or “below” mean a stacking order in which a plurality of layers is stacked, and may be a positional relationship in which a transistor and a pixel electrode do not overlap each other in a plan view when expressed as a pixel electrode above a transistor. On the other hand, when expressed as a pixel electrode vertically above a transistor, it means a positional relationship in which the transistor and the pixel electrode overlap each other in a plan view.

In this specification, the expressions “a includes A, B or C,” “a includes any of A, B, or C,” and “a includes one selected from a group consisting of A, B, and C,” and the like do not exclude the case where a includes a plurality of combinations of A to C unless otherwise indicated. Furthermore, these expressions do not exclude the case where a includes other elements.

### First Embodiment

### 1. Configuration of Display Device

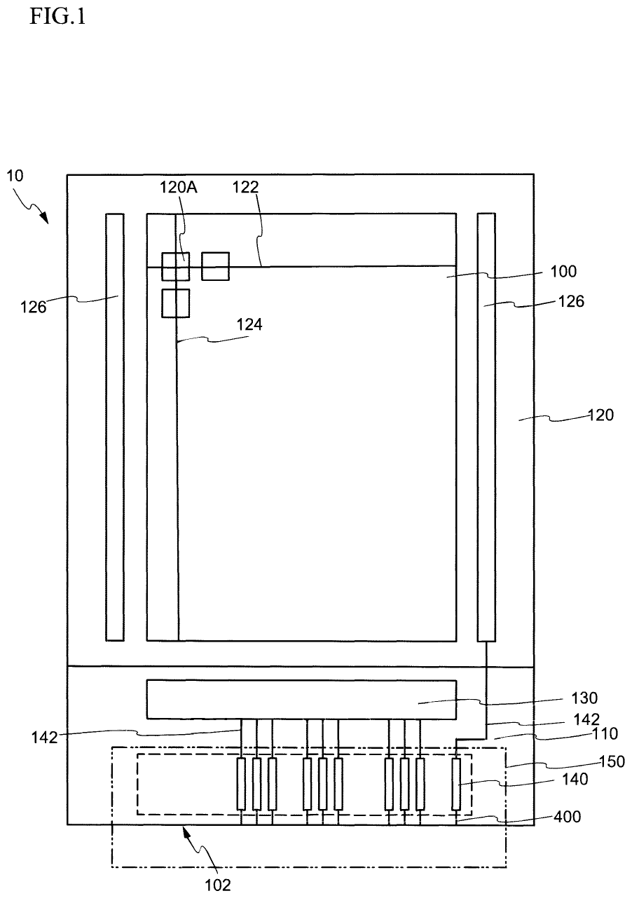

FIG. 1 shows a configuration of a display device during the manufacturing of a display device 10 according to an embodiment of the present invention. FIG. 1 shows a top view of a display device during the manufacturing of the display device 10. The display device 10 is a flexible display device formed to be thin as a whole. The display device 10 includes a substrate 110, a display part 120, a driving circuit 130, a plurality of terminals 140, a flexible printed circuit 150, a plurality of wirings 135, and a plurality of wirings 400.

The substrate 110 is a substrate having plasticity. In this case, the substrate 110 may be referred to as a substrate, a base film, or a sheet base substrate. The substrate 110 here is an organic resin substrate containing resin. For example, an organic resin material constituting the substrate 110 is polyimide, acryl, epoxy, and polyethylene terephthalate. For example, a thickness of the substrate 110 is between 10 μm and several hundred μm.

The display part 120, the driving circuit 130, the plurality of terminals 140, and a plurality of wirings 142 are respectively arranged on an upper surface of the substrate 110. The display part 120 displays a still image or a moving image on a display region 100. The driving circuit 130 and the plurality of terminals 140 are arranged in a peripheral region of the display region 100 along the same side of the display region 100. The driving circuit 130 is arranged between the display region 100 and the plurality of terminals 140. The plurality of wirings 142 is wiring electrically connected to the plurality of terminals 140, and is arranged between the plurality of terminals 140 and a scanning line driving circuit 126 or the driving circuit 130.

The display part 120 includes a pair of scanning line driving circuits 126 in addition to the display region 100. In the display region 100, the display part 120 includes a plurality of scanning lines 122 extending in a first direction and a plurality of signal lines 124 extending in a second direction intersecting the first direction. The pair of scanning line driving circuits 126 is arranged at positions opposed to each other across the display region 100. The pair of scanning line driving circuits 126 is arranged in the peripheral region of the display region 100 different from the driving circuit 130 and the plurality of terminals 140. The pair of scanning line driving circuits 126 selects the scanning line 122 electrically connected to itself in a predetermined order and supplies a control signal.

The driving circuit 130 is electrically connected to a plurality of pixels 120A and drives the display part 120 to control the plurality of pixels 120A for displaying images. The driving circuit 130 supplies a data voltage to the plurality of data signal lines 124 in a predetermined order. The driving circuit 130 may control the scanning line driving circuit 126. For example, the driving circuit 130 includes an integrated circuit such as an ASIC (Application Specific Integrated Circuit). As described above, in the case where the driving circuit 130 includes the integrated circuit such as the ASIC, the driving circuit 130 may be adhered to the substrate 110 using an adhesive. The adhesive includes resin and includes a material that is cured by ultraviolet light. For example, the adhesive may include a UV cured film. For example, the UV-cured film includes polymerizable resins such as acrylic and epoxy resin.

In addition, the scanning line driving circuit 126 and the driving circuit 130 are not mounted on the display device 10, and an external driving circuit is connected to the plurality of terminals 140 electrically connected to the plurality of scanning lines 122 and the plurality of data signal lines 124, so that the plurality of pixels 120A can be driven by a signal supplied from the external driving circuit. A driving IC (Integrated Circuit) can be used as the external driving circuit.

For example, the driving IC may be mounted on the substrate 110 by a COF (Chip On Film) method using an anisotropic conductive film (ACF). In this case, for example, an FOG (Film On Glass) in which a wiring substrate is mounted using the anisotropic conductive film can be used as the terminal 140.

The pixel 120A is arranged corresponding to each intersection between the plurality of scanning lines 122 and the plurality of signal lines 124. The plurality of pixels 120A is arranged in an array here.

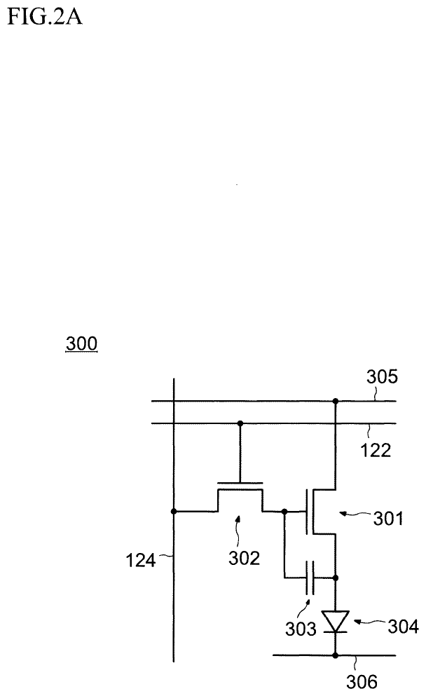

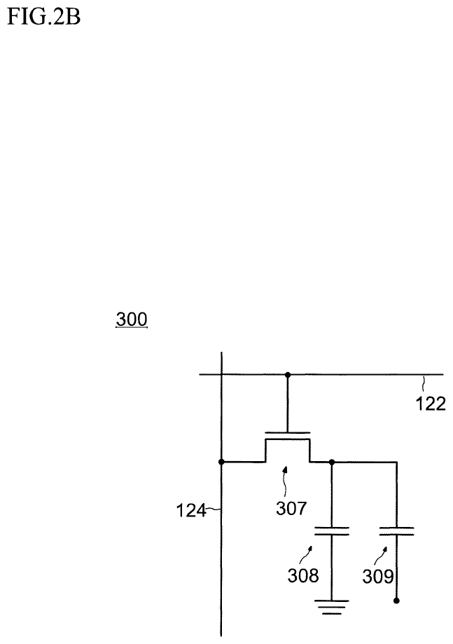

In this case, a pixel circuit 300 for controlling each pixel 120A will be described with reference to FIG. 2A and FIG. 2B. FIG. 2A shows an example of a pixel circuit using a light-emitting element (organic EL element) utilizing organic electroluminescence for the pixel 120A. In addition, FIG. 2B shows an example of a pixel circuit using a liquid crystal element for the pixel 120A.

FIG. 2A is a diagram showing a configuration of the pixel circuit 300 in the display device 10 according to an embodiment of the present invention. For convenience of explanation, a basic configuration using two semiconductor devices (thin-layer transistor) will be exemplified and described. As shown in FIG. 2A, the pixel circuit 300 includes elements such as a drive transistor 301, a selection transistor 302, a storage capacitor 303, and a light-emitting element 304. The drive transistor 301 and the selection transistor 302 are composed of a semiconductor device such as a thin-layer transistor.

A source of the drive transistor 301 is connected to an anode power line 305, and the drive transistor 301 is connected to one end (anode) of the light-emitting element 304. The other end (cathode) of the light-emitting element 304 is connected to a cathode power line 306. In the present embodiment, a higher power supply voltage is applied to the anode power line 305 than a power supply voltage applied to the cathode power line 306. In FIG. 1, the anode power line 305 is not shown.

A gate of the selection transistor 302 is connected to the scanning line 122 and a source of the selection transistor 302 is connected to the data signal line 124. A drain of the selection transistor 302 is connected to the gate of the drive transistor 301. In addition, the source and the drain of the selection transistor 302 may be switched depending on the relationship between the voltage applied to the data signal line 124 and the voltage stored in the storage capacitor 303.

The storage capacitor 303 is connected to the gate and the drain of the drive transistor 301 and the drain of the selection transistor 302. A gradation signal that determines the emission intensity of the light-emitting element 304 is supplied to the data signal line 124. A scanning signal for selecting a pixel to which the gradation signal is written is supplied to the scanning line 122.

Next, an example in which a liquid crystal element is used for the pixel 120A will be described with reference to FIG. 2B.

FIG. 2B is a diagram showing a configuration of the pixel circuit 300 in the display device 10 according to an embodiment of the present invention. As shown in FIG. 2B, the pixel circuit 300 includes elements such as a transistor 307, a storage capacitor 308, and a liquid crystal element 309. The transistor 307 is composed of a semiconductor device such as a thin-layer transistor.

A gate of the transistor 307 is connected to the scanning line 122 and a source of the transistor 307 is connected to the data signal line 124. A drain of the transistor 307 is connected to the storage capacitor 308 and the liquid crystal element 309. Although not shown, one electrode of the storage capacitor 308 is connected to the drain of the transistor 307, and the other electrode is connected to a common electrode of the pixel 120A. In addition, one electrode of the liquid crystal element 309 is connected to the drain of the transistor 307 via a pixel electrode, and the other electrode is connected to the common electrode. Further, the source and the drain of the transistor 307 may be switched depending on the relationship between the voltage applied to the data signal line 124 and the voltage stored in the storage capacitor 308.

The description is returned to FIG. 1. The plurality of terminals 140 is electrically connected to the flexible printed circuit 150. Each of the plurality of terminals 140 is electrically connected to the display part 120 or the driving circuit 130. A signal or a power supply potential supplied from the flexible printed circuit 150 is input to the plurality of terminals 140. The signal is a signal for operating the display part 120, and is, for example, an image signal showing an image to be displayed on the display region 100 or a control signal for controlling the scanning line driving circuit 126 or the driving circuit 130. In addition, the number of terminals 140 included in the display device 10 may be any number as long as the number is plural.

The flexible printed circuit 150 outputs a signal input from an external circuit (not shown) to the plurality of terminals 140. The flexible printed circuit 150 has a configuration in which the plurality of wirings is arranged in a substrate having flexibility. Each of the plurality of wirings is electrically connected to any one of the plurality of terminals 140.

One end of each of the plurality of wirings 400 is electrically connected to the terminal 140 and the other end is positioned at a periphery 102. That is, when the display device is viewed from the top, the periphery 102 and the other end of the plurality of wirings 400 are present at the same position. The manufacturing process of the display device 10 includes a cutting step for cutting the substrate 110 to shape the display device 10. The periphery 102 is a periphery of the substrate 110 formed by the cutting step.

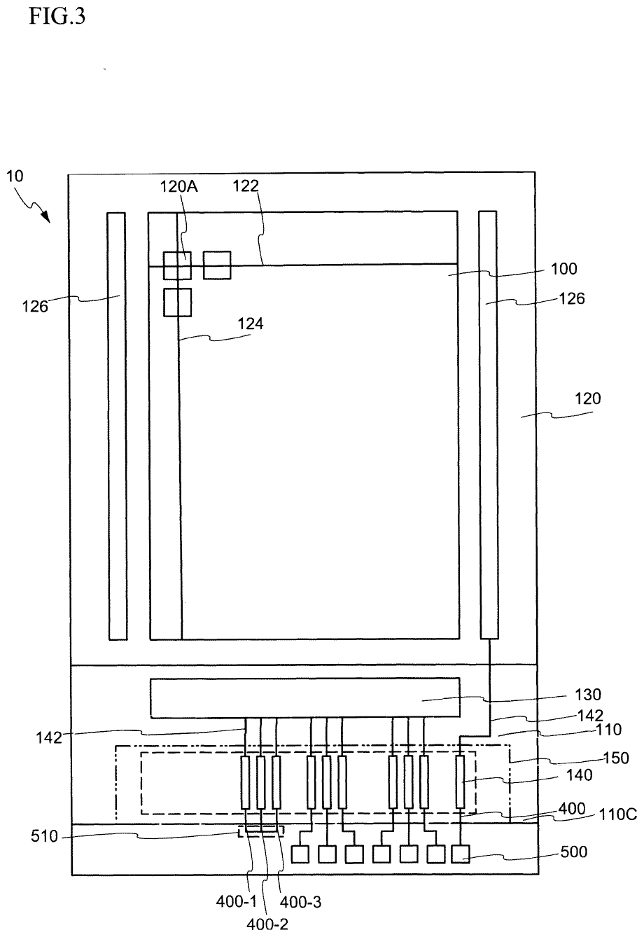

The substrate 110 before the cutting step for cutting the substrate 110 will be described with reference to FIG. 3.

### 2. Configuration of Display Device During Manufacturing

FIG. 3 is a top view showing a configuration of a display device during the manufacturing of the display device 10. The method for manufacturing the display device 10 includes a forming step for forming the plurality of terminals 140 and the plurality of wirings 400 on the substrate 110 arranged on a glass substrate (not shown). In the forming step, a transistor, a light-emitting element, and the like included in the display part 120 may be formed in the substrate 110.

In addition to the display part 120, as shown in FIG. 3, a test pad 500, a short ring 510, and the like may be formed between the display part 120 and an end portion of the substrate 110.

The short ring 510 is electrically connected to the driving circuit 130, the scanning line driving circuit 126, the pixel circuit 300, the scanning line 122, the data signal line 124, and the like that are composed of the transistor arranged in the display part 120, and is arranged so as to discharge static electricity generated in the manufacturing process of the display device 10 and suppress the display device 10 from being electrostatically destroyed.

The test pad 500 is electrically connected to the driving circuit 130, the scanning line driving circuit 126, the pixel circuit 300, and the like, composed of the transistor arranged in the display part 120, and can be used for testing before shipping the display device 10.

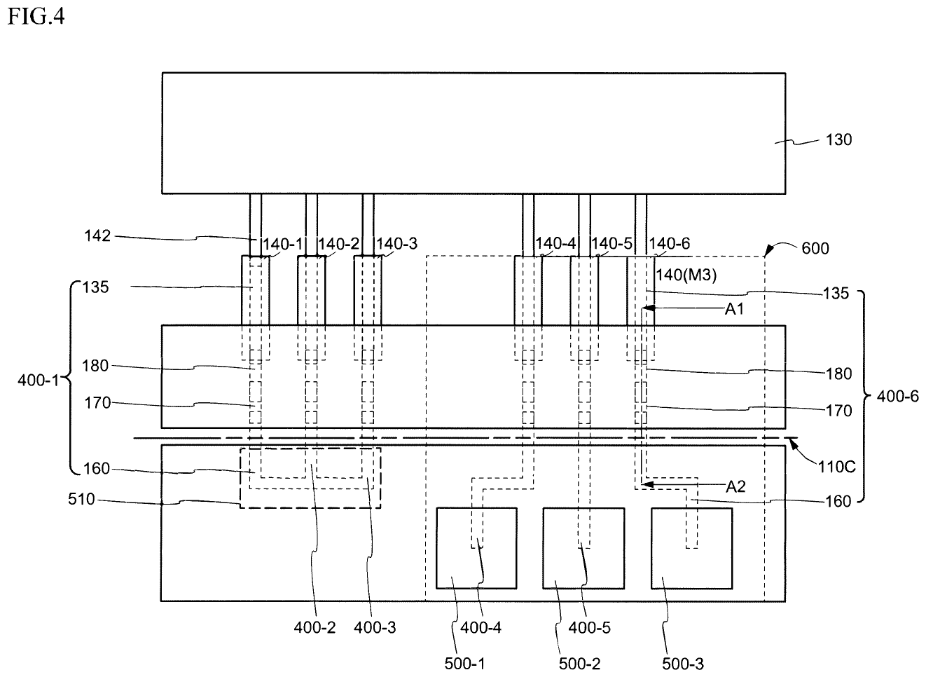

The wiring 400 constituting the short ring 510 and the wiring 400 connecting the test pad 500 and the terminal 140 will be described with reference to FIG. 4.

FIG. 4 shows a configuration of the terminal 140 of the display device and its periphery during manufacturing of the display device 10. The display device 10 includes the wiring 400 constituting the short ring 510 and the wiring 400 connecting the test pad 500 and the terminal 140. In the wiring 400 constituting the short ring 510, end portions of a wiring 400-1, a wiring 400-2, and a wiring 400-3 extending from the plurality of terminals 140 are electrically or directly connected to each other, and the wirings are short-circuited. In FIG. 4, although an example in which the short ring 510 is configured by the wiring 400 extending from three terminals 140 is shown, the number of wirings 400 may be plural, and may be configured by the wiring 400 extending from two terminals 140, or may be configured by the wiring 400 extending from four or more terminals 140.

Although details will be described later, an active layer of the transistor arranged in the display part 120, for example, an oxide semiconductor layer can be used as the wiring 400 constituting the short ring 510 and the wiring 400 connecting the test pad 500 and the terminal 140.

Further, as described above, in the wiring 400 constituting the short ring 510, in the manufacturing process of the display device 10, the short ring 510 may be formed by first forming a short-circuiting part of the wiring using polysilicon or the like in a process of forming a structure in which electrostatic breakdown is likely to occur, and then forming a wiring for connecting the terminal 140 and the short ring 510 in a process of forming the oxide semiconductor layer of the transistor.

Further, as shown in FIG. 4, the wiring 400 can be composed of a wiring formed in the same process as the transistor of the display part 120 and the electrode used in the element. For example, each of the wirings 400-1 to 400-3 used for the short ring 510 is composed of a wiring 160, a wiring 170, a wiring 180, the wiring 135, and are short-circuited to each other in the wiring 160. In addition, a wiring 400-6 connecting a test pad 500-3 and a terminal 140-6 is also composed of the wiring 160, the wiring 170, the wiring 180, and the wiring 135. In this case, a cutline 110C is arranged to cut the wiring 400, and is arranged to cut the wiring 160 constituting the wiring 400.

The cutline 110C passes between the test pad 500, the short ring 510, and the position where the plurality of wirings 400 is short-circuited. The cutting step of the substrate 110 in the cutline 110C is performed using a laser after the structure arranged above the substrate 110 is formed. Therefore, the plurality of wirings 400 is separated from each other, and the test pad 500 and the short ring 510 are removed from the display device 10, resulting in the display device 10 shown in FIG. 1.

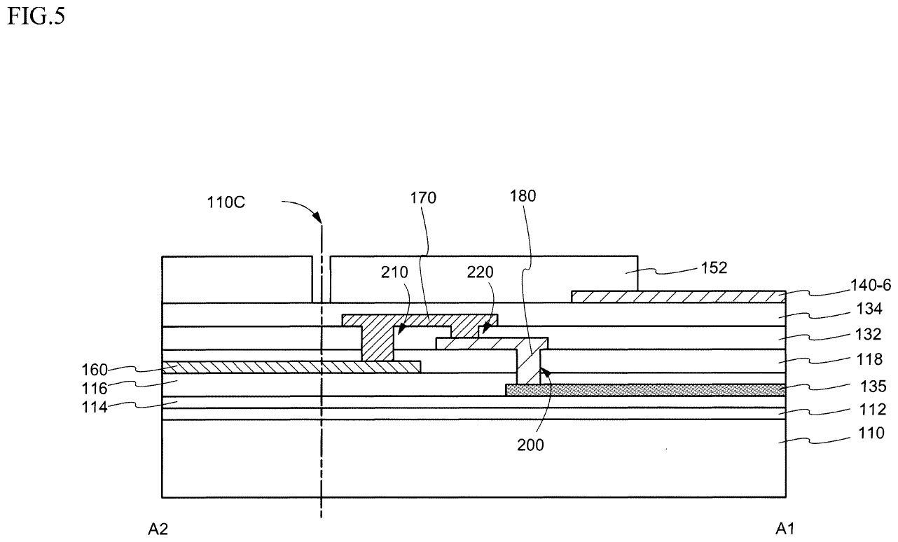

Details of the wiring 400 connecting the test pad 500 from the terminal 140 will be described with reference to FIG. 5.

FIG. 5 is an end view of a terminal of the display device and its periphery during the manufacturing of the display device according to an embodiment of the present invention. Specifically, FIG. 5 corresponds to an end view showing a cross-section taken along A1-A2 of FIG. 4.

The display device during the manufacturing of the display device 10 has the substrate 110. A base film 112 may be arranged above the substrate 110. The base film 112 can prevent contamination from the substrate 110, for example, an inorganic insulating material can be used for the base film 112. For example, silicon nitride, silicon oxide, a composite thereof, and a stacked structure of these can be used as the inorganic insulating material.

An insulating layer 114 may be arranged above the base film 112. The insulating layer 114 may have a function as a gate insulating layer of the transistor included in the pixel 120A, the scanning line driving circuit 126, and the driving circuit 130 in the display region 100. The same material as the base film 112 can be used for the insulating layer 114. A CVD (Chemical Vapor Deposition) film using a TEOS (Tetraethoxysilane), which is a deposited film of silicon oxide, is preferably used for the insulating layer 114 in particular.

The wiring 135 may be arranged above the insulating layer 114. The wiring 135 is connected to the terminal 140 and electrically connected to the transistor arranged in the display part 120. For example, a material containing titanium, aluminum, copper, molybdenum, or the like as a main component can be used for the wiring 135, and a single layer or a stacked layer thereof can be used. In the case where the transistor arranged in the display part 120 has a bottom-gate structure or a dual-gate structure, the wiring 135 may be formed in the same process as a bottom-gate electrode of the transistor.

An insulating layer 116 may be arranged above the wiring 135 and the insulating layer 114 so as to cover the wiring 135 and the insulating layer 114. The insulating layer 116 may also function as a planarization layer for a wiring 172 and a wiring 138. In the case where the transistor arranged in the display part 120 has the bottom-gate structure or the dual-gate structure, the insulating layer 116 may be formed in the same process as the insulating layer arranged between the bottom-gate electrode and the active layer of the transistor. The same material and configuration as the base film 112 can be used for the insulating layer 116.

The wiring 160 may be arranged above the insulating layer 116. The same material as the active layer of the transistor arranged in the display part 120 can be used for the wiring 160. In addition, the wiring 160 can be formed in the same process as the process for forming the active layer of the transistor arranged in the display part 120. Although details will be described later, an oxide semiconductor layer can be used as the active layer of the transistor, and the oxide semiconductor layer can be used for the wiring 160 by reducing the resistance of the oxide semiconductor layer. Therefore, the wiring 160 is an oxide conductive layer having the same composition as the active layer of the transistor arranged in the display part 120.

As shown in FIG. 4, the wiring 160 is connected to the test pad 500-3 but can be connected to the test pad 500-3 by, for example, connecting to a wiring formed in the same layer as the wiring 170 shown in FIG. 5 and connecting the wiring formed in the same layer as the wiring 170 to the test pad 500-3.

An insulating layer 118 may be arranged above the wiring 160 and the insulating layer 116. In the case where the transistor arranged in the display part 120 has a top-gate structure or a dual-structure, the insulating layer 118 may be formed in the same process as the process for forming the insulating layer 118 arranged between the active layer and the gate electrode of the transistor. The same material and configuration as the base film 112 can be used for the insulating layer 118.

The wiring 180 may be arranged above the insulating layer 118. The wiring 180 may be formed in the insulating layer 118 and in an opening 200 reaching the wiring 135 in the insulating layer 118, and the wiring 180 is connected to the wiring 135. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof can be used as the wiring 180. In the wiring 180, the above-described material may be used in a single-layer structure or a stacked structure.

An insulating layer 132 may be arranged above the wiring 180 and the insulating layer 118. The insulating layer 132 may be a single-layer or stacked structure. For example, silicon nitride, silicon oxide, or the like can be used for the insulating layer 132. In the case where the stacked structure is used for the insulating layer 132, silicon nitride is preferably used as a film in contact with the wiring 180, and silicon oxide is preferably used thereon.

The wiring 170 may be arranged above the insulating layer 132. The wiring 170 may be formed in the insulating layer 132 and the insulating layer 118 at an opening 210 reaching the wiring 160, and the wiring 170 is connected to the wiring 160. In addition, the wiring 170 is formed in the insulating layer 132 at an opening 220 reaching the wiring 180 and may be connected to the wiring 180. Therefore, the wiring 170 may have a function of electrically connecting the wiring 160 and the wiring 180. The wiring 170 can be formed in the same process as the process for forming the source electrode and the drain electrode of the transistor arranged in the display part 120. The wiring 170 may be formed using a general metal material. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof can be used as the metal material. The wiring 170 may have a single-layer structure or a stacked structure.

An insulating layer 134 may be arranged above the wiring 170 and the insulating layer 132. The same material and configuration as the base film 112 can be used for the insulating layer 134. In addition, silicon nitride is preferably used for the insulating layer 134.

The terminal 140 may be arranged above the insulating layer 132. As shown in FIG. 5, the terminal 140-6 has a portion exposed from an insulating layer 152, and the exposed portion can be connected to a driving IC such as the COF. Further, although not shown, the terminal 140 is electrically or directly connected to the wiring 135 either between the display part 120, the display part 120, and the terminal 140. For example, since the terminal 140 is connected to the wiring formed in the same layer as the wiring 170, the wiring formed in the same layer as the wiring 170 is connected to the wiring formed in the same layer as the wiring 180, and the wiring formed in the same layer as the wiring 180 is connected to the wiring 135, the terminal 140 and the wiring 135 can be electrically connected to each other. The material used for the wiring 170 may be used for the terminal 140.

The insulating layer 152 may be arranged above the insulating layer 134. The insulating layer 152 may be partially arranged on the terminal 140 such that the termina 140 is partially exposed as described above. A light-emitting element or a liquid crystal element arranged in the pixel 120A is formed above the insulating layer 152. A photosensitive organic resin material including acryl resin, polysiloxane, polyimide, polyester, or the like can be used as the insulating layer 152, and can function as an organic insulating layer.

The insulating layer 152 is not arranged above the cutline 110C and no cross-sectional surface of the insulating layer 152 is formed when the substrate 110 is cut along the cutline 110C. However, the layers arranged below the insulating layer 152 and the substrate 110 are divided along the cutline 110C, and each layer, each film, and the substrate 110 have cross-sectional surfaces. In addition, the cross-sectional surfaces are substantially flat without a step in a cross-sectional view.

Specifically, as shown in FIG. 5, the cross-sectional surfaces of the base film 112, the insulating layer 114, the insulating layer 116, the insulating layer 118, the wiring 160, the insulating layer 132, and the insulating layer 134 are formed along the cutline 110C. The cross-sectional surface along the cutline 110C corresponds to the periphery 102 of the substrate 110 in a plan view. Therefore, the cross-sectional surfaces of the base film 112, the insulating layer 114, the insulating layer 116, the insulating layer 118, the wiring 160, the insulating layer 132, and the insulating layer 134 are cross-sectional surfaces along the periphery 102 of the substrate 110.

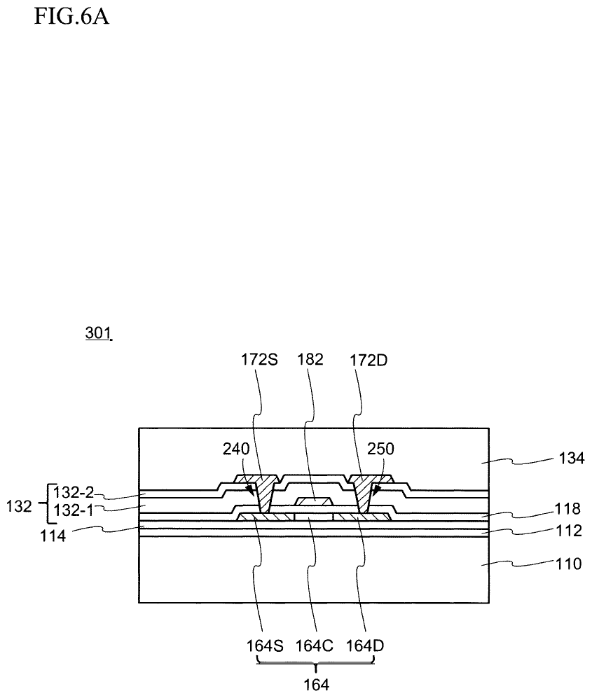

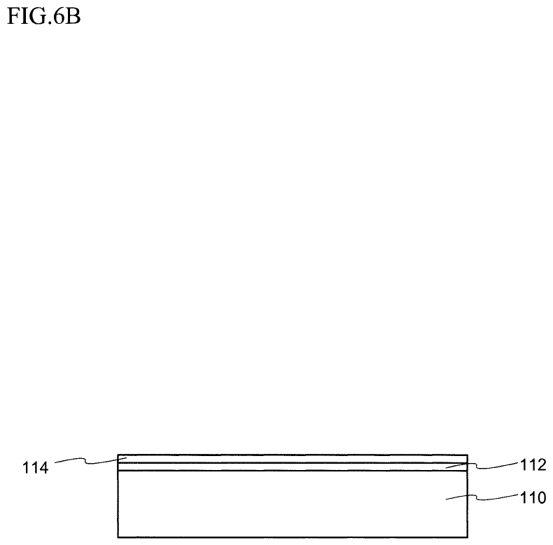

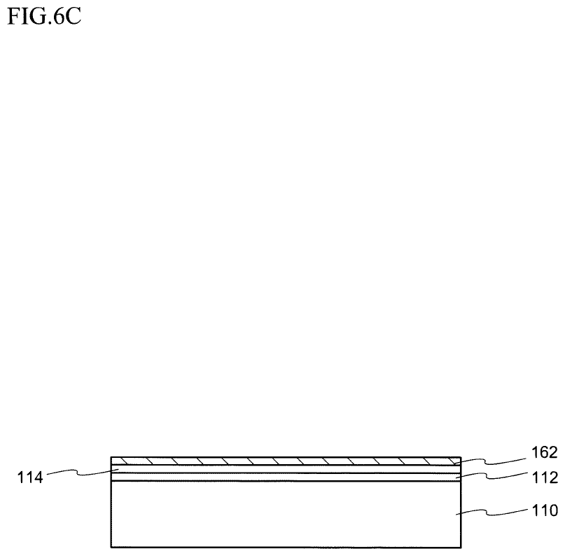

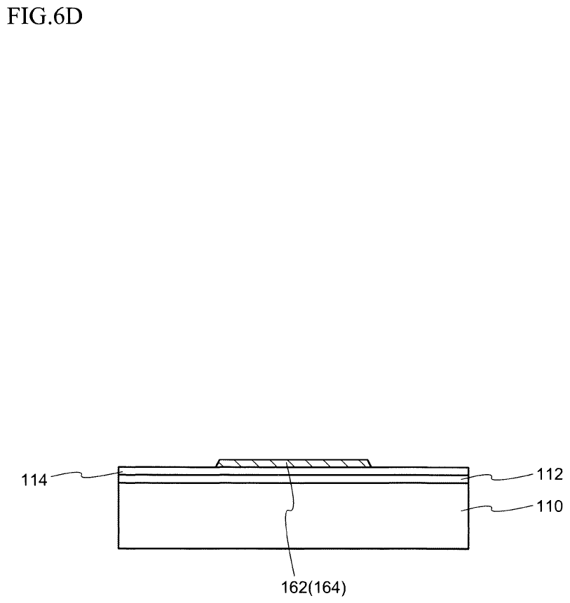

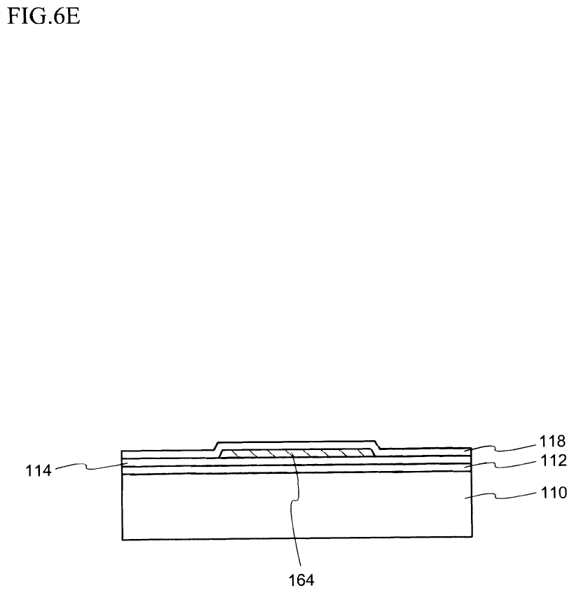

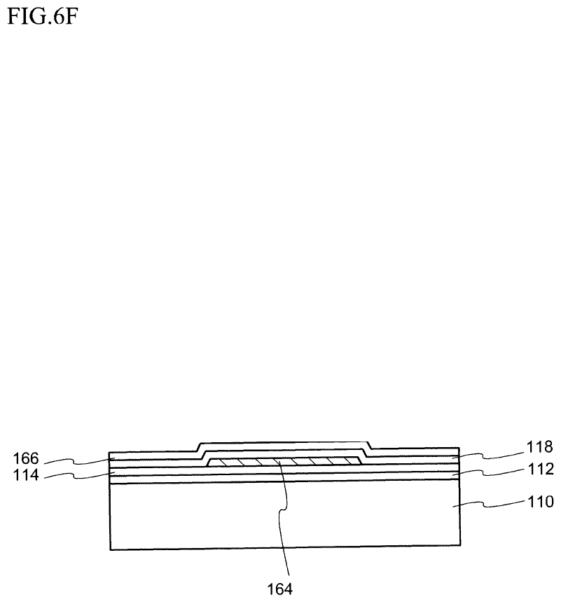

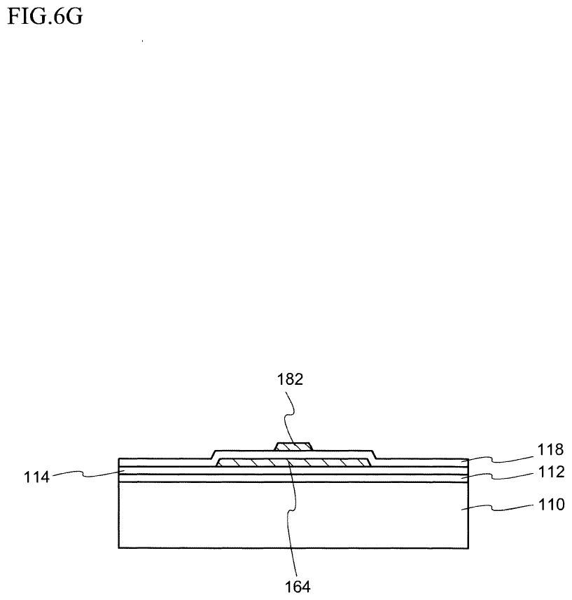

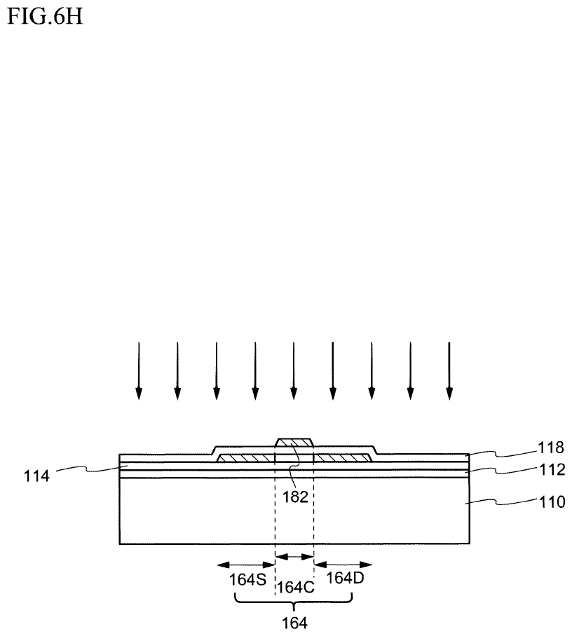

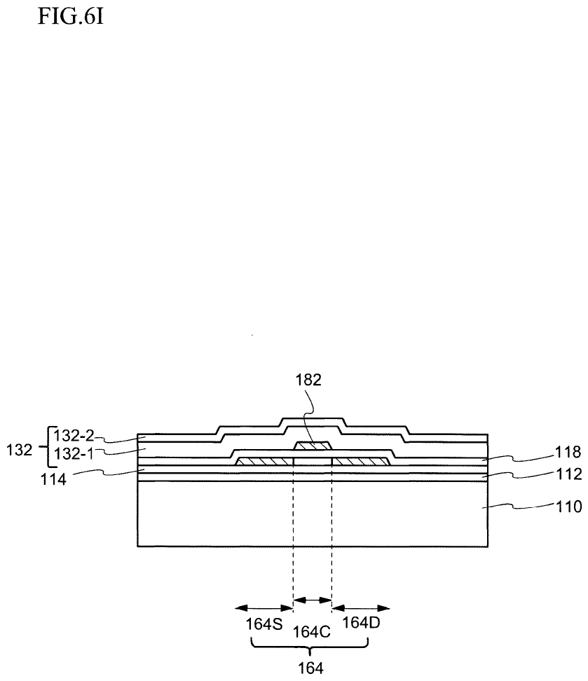

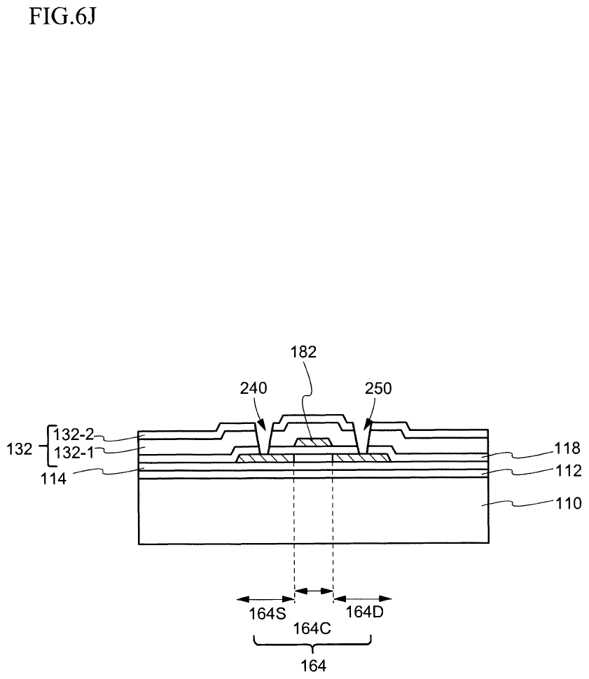

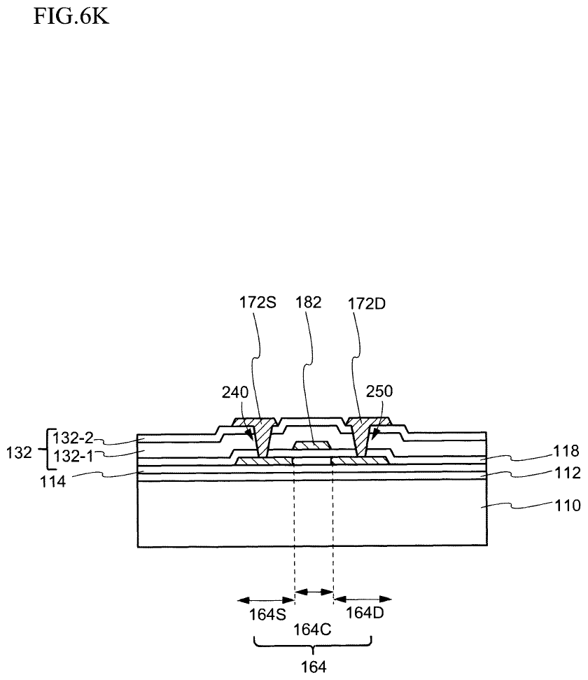

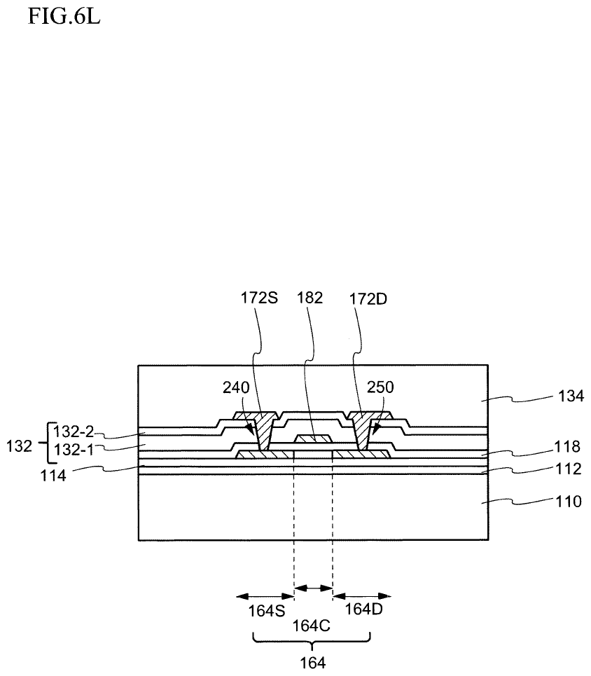

Referring to the end view of the terminal of the display device and its periphery during the manufacturing of the display device 10, it has been described that the manufacturing process proceeds together with the manufacturing process of the transistor arranged in the display part 120. An example of the manufacturing process of the transistor arranged in the display part 120 will be described with reference to FIG. 6B to FIG. 6J. FIG. 6B to FIG. 6J are diagrams illustrating a method for manufacturing a display device according to an embodiment of the present invention. For example, a method for manufacturing a transistor shown in FIG. 6B to FIG. 6J relates to a top-gate transistor shown in FIG. 6A.

### 3. Method for Manufacturing Display Device

FIG. 6A is an end view showing a configuration of a display device according to an embodiment of the present invention. The top-gate structure is often used for a transistor in which an organic EL element is arranged in a display device. Therefore, the transistor shown in FIG. 6A is, for example, the drive transistor 301 shown in FIG. 2A.

As shown in FIG. 6A, the drive transistor 301 includes the base film 112, the insulating layer 114, an oxide semiconductor layer 164, the insulating layer 118, a gate electrode 182, an insulating layer 132-1, an insulating layer 132-2, a source electrode 172S, and a drain electrode 172D above the substrate 110.

Next, a method for manufacturing the drive transistor 301 will be described.

The base film 112 and the insulating layer 114 are formed above the substrate 110, as shown in FIG. 6B.

Next, as shown in FIG. 6C, an oxide semiconductor layer 162 is formed above the insulating layer 114. A metal oxide having semiconductor properties may be used as the oxide semiconductor layer 162. For example, an oxide semiconductor containing two or more metals including indium (In) is used as the oxide semiconductor layer 162. The ratio of indium in the two or more metals is 50% or more. Gallium (Ga), zinc (Zn), aluminum (Al), hafnium (Hf), yttrium (Y), zirconia (Zr), or lanthanoids are used as the oxide semiconductor layer 162 in addition to indium. Elements other than those described above may be used as the oxide semiconductor layer 162. In the present embodiment, a metal oxide (IGO-based oxide semiconductor) containing indium (In) and gallium (Ga) is used as the oxide semiconductor layer 162.

In the case where the oxide semiconductor layer 162 is crystallized by the firing of the oxide semiconductor layer 162, the oxide semiconductor layer 162 after the film formation and before the firing of the oxide semiconductor layer 162 is preferably amorphous (a state where a crystalline component of the oxide semiconductor is small). In other words, a condition of the method for forming the oxide semiconductor layer 162 is preferably such that the oxide semiconductor layer 162 immediately after the film formation does not crystallize as much as possible. For example, in the case where the oxide semiconductor layer 162 is formed by a sputtering method, the oxide semiconductor layer 162 is formed while controlling the temperature of an object to be formed, for example, the substrate 110. In order to control the temperature of the object to be formed, for example, film formation is performed while cooling the object to be formed. For example, in order for the temperature of a film-forming surface of the object to be formed (hereinafter, referred to as “film-forming temperature”) to be 100° C. or less, 70° C. or less, 50° C. or less, or 30° C. or less, the object to be formed is preferably cooled from the surface opposite to the film-forming surface. Forming the oxide semiconductor layer 162 while cooling the object to be formed as described above makes it possible to form the oxide semiconductor layer 162 with few crystalline components immediately after the film formation.

Next, as shown in FIG. 6D, a pattern of the oxide semiconductor layer 162 is formed. The pattern of the oxide semiconductor layer 162 is preferably formed before the firing of the oxide semiconductor layer 162. When the oxide semiconductor layer 162 is crystallized by the firing of the oxide semiconductor layer 162, it tends to be difficult to etch. Further, even if the oxide semiconductor layer 162 is damaged by etching, the damage can be repaired by the firing of the oxide semiconductor layer 162.

The firing of the oxide semiconductor layer 162 is performed after the formation of the pattern of the oxide semiconductor layer 162. In the firing of the oxide semiconductor layer 162, the oxide semiconductor layer 162 is held at a predetermined reaching temperature for a predetermined time. The predetermined reaching temperature is 300° C. or more and 500° C. or less, preferably 350° C. or more and 450° C. or less. In addition, the holding time at the reaching temperature is 15 minutes or more and 120 minutes or less, preferably 30 minutes or more and 60 minutes or less. Firing the oxide semiconductor layer 162 crystallizes the oxide semiconductor layer 162 and the oxide semiconductor layer 164 with a polycrystalline structure is formed.

Next, as shown in FIG. 6E, the insulating layer 118 is formed above the oxide semiconductor layer 162. The insulating layer 118 is preferably an insulating layer with few defects. In order to form the insulating layer with few defects as the insulating layer 118, the insulating layer 118 may be formed at a film-forming temperature of 350° C. or higher. Further, after the insulating layer 118 is formed, a process of implanting oxygen may be performed on a part of the insulating layer 118. The insulating layer 118 may function as a gate insulating layer.

Next, as shown in FIG. 6F, a metal oxide layer 166 containing aluminum as a main component is formed above the insulating layer 118, is fired, and then the metal oxide layer 166 is removed.

An inorganic insulating layer such as aluminum oxide (AlOₓ), aluminum oxynitride (AlOₓN_{y}), aluminum nitride oxide (AlNₓO_{y}), and aluminum nitride (AlNₓ) are used for the metal oxide layer 166. In this case, the ratio of aluminum contained in the metal oxide layer 166 may be 1% or more of the entire metal oxide layer 166. In addition, the ratio of aluminum contained in the metal oxide layer 166 may be 5% or more and 70% or less, 10% or more and 60% or less, or 30% or more and 50% or less of the entire metal oxide layer 166.

For example, a thickness of the metal oxide layer 166 may be 5 nm or more and 100 nm or less, 5 nm or more and 50 nm or less, 5 nm or more and 30 nm or less, or 7 nm or more and nm or less.

After the metal oxide layer 166 is formed, the metal oxide layer 166 is fired. After firing the metal oxide layer 166, the metal oxide layer 166 is removed. At least part of the metal oxide layer 166 overlapping the oxide semiconductor layer 164 may be entirely removed.

Next, as shown in FIG. 6G, the gate electrode 182 is formed above the insulating layer 118. The gate electrode 182 is formed to be in contact with the exposed the insulating layer 118 by removing the metal oxide layer 166.

A source region 164S and a drain region 164D of the oxide semiconductor layer 164 are formed. Specifically, an impurity element is implanted into the oxide semiconductor layer 164 via the insulating layer 118 using the gate electrode 182 as a mask by ion implantation or an ion doping method. For example, an impurity element such as argon (Ar), phosphorus (P), or boron (B) is implanted into part of the oxide semiconductor layer 164 not covered with the gate electrode 182. Implanting such impurities into part of the oxide semiconductor layer 164 reduces resistance at that part. Specifically, the source region 164S and the drain region 164D sandwiching a channel region 164C of the oxide semiconductor layer 164 shown in FIG. 6H correspond to part of the oxide semiconductor layer 164 not covered with the gate electrode 182, and the impurity element is implanted. Since the channel region 164C of the oxide semiconductor layer 164 is covered with the gate electrode 182, no impurity elements are implanted.

In this case, the wiring 160 shown in FIG. 5 is also formed in the same process as the active layer of the drive transistor 301. Since there is no part covered by the gate electrode such as the drive transistor 301, the impurity element is implanted into the entire wiring 160. Therefore, since the wiring 160 has the same composition as the oxide semiconductor layer 164 and the resistance is reduced by implantation of the impurity element, it becomes an oxide conductive layer. Since the impurity element is implanted into the wiring 160, which is the oxide conductive layer, similar to the source region 164S and the drain region 164D as described above, the wiring 160 contains the same impurity element as the source region 164S and the drain region 164D.

Next, as shown in FIG. 6I, the insulating layer 132-1 and the insulating layer 132-2 are formed above the gate electrode 182 and the insulating layer 118.

Next, as shown in FIG. 6J, an opening 240 and an opening 250 are formed in the insulating layer 118, the insulating layer 132-1, and the insulating layer 132-2. The opening 240 exposes the source region 164S and the opening 250 exposes the drain region 164D. When the source region 164S and the drain region 164D are exposed by the opening 240 and the opening 250, the source electrode 172S and the drain electrode 172D shown in FIG. 6K are formed.

The drive transistor 301 can be formed through the above-described manufacturing process.

Further, in the case where an organic EL element or liquid crystal element is mounted on the display device 10, the insulating layer 152 shown in FIG. 5 is formed above the insulating layer 134 to form the organic EL element or liquid crystal element. As shown in FIG. 6L, the insulating layer 134 is formed above the insulating layer 132, the source electrode 172S, and the drain electrode 172D. The terminal 140 shown in FIG. 5 is formed above the insulating layer 134.

The wiring 400 and the terminal 140 can be formed together with each manufacturing step of the transistor described above.

### 4. Modification of Display Device During Manufacturing

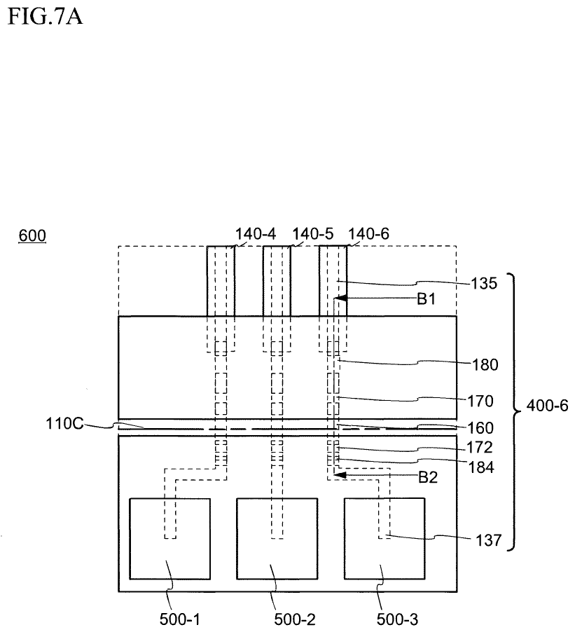

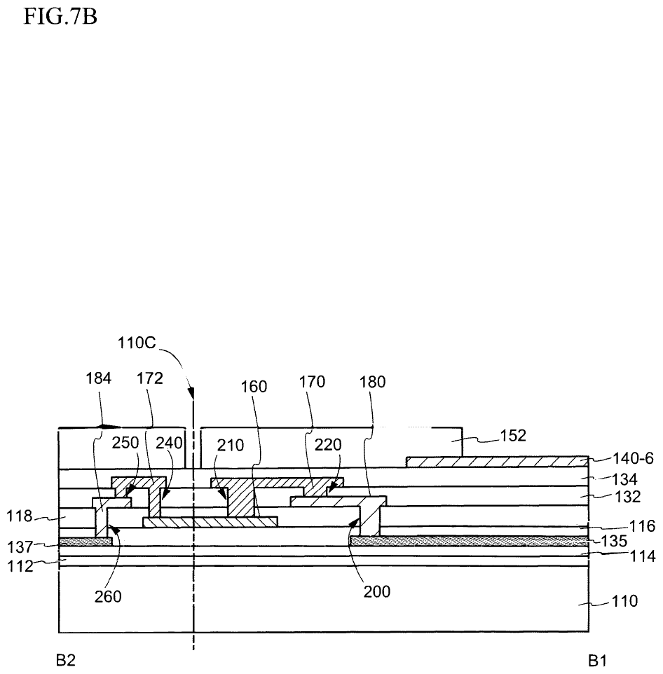

A modification of a display device during the manufacturing of the display device 10 will be described with reference to FIG. 7A and FIG. 7B. FIG. 7A is a top view showing a terminal of a display device and its periphery during the manufacturing of a display device according to an embodiment of the present invention. FIG. 7B is an end view showing a terminal of a display device and its periphery during the manufacturing of a display device according to an embodiment of the present invention. Specifically, FIG. 7B corresponds to an end view showing a cross-section taken along the line B1-B2 of FIG. 7A.

A difference from the display device during the manufacturing of the display device 10 shown in FIG. 4 and FIG. is that the wiring 160, which is an oxide conductive layer, is used only for a wiring that bridges the cutline 110C, and a metal wiring is used for a wiring that connects the wiring 160 and the test pad 500. In addition, descriptions of the same or similar configuration as the display device 10 shown in FIG. 1 to FIG. 6 or the display device during manufacturing may be omitted.

FIG. 7A and FIG. 7B show a partial structure 600 shown in FIG. 4. As shown in FIG. 7A and FIG. 7B, the wiring 172 and a wiring 137 are arranged between the cutline 110C and the test pad 500-3. The wiring 172 connects to the wiring 160, which bridges the cutline 110C, via the opening 240. A wiring 184 is connected to the wiring 172 via the opening 250, and is connected to the wiring 137 via the opening 260. The wiring 137 connects to the test pad 500-3.

The wiring 172 is formed in the same layer as the wiring 170 and is formed in the same manner as the wiring 170. The wiring 184 is formed in the same layer as the wiring 180 and is formed in the same manner as the wiring 180. The wiring 137 is formed in the same layer as the wiring 135 and is formed in the same manner as the wiring 135.

As shown in FIG. 7A and FIG. 7B, using a metal wiring closer to the test pad 500 than the cutline 110C makes it possible to reduce the wiring resistance of the wiring 400 composed of the above described wirings.

In the display device 10 of the present embodiment, the oxide conductive layer formed in the same manner as the source region 164S and the drain region 164D of the oxide semiconductor layer of the transistor can be used for the short ring 510 and the wiring 160 connecting the test pad 500 and the terminal 140. The short ring 510 and the test pad 500 are removed before shipping the display device 10. Therefore, although the wiring 160 connecting them with the terminal 140 is divided, the oxide conductive layer is used for the wiring 160, so that the cross-sectional surface is less likely to corrode. In addition, using the metal wiring on a side closer to the test pad 500 than the cutline 110C as the wiring 400 reduces the wiring resistance of the wiring 400, and the variation in the test of the electric properties in the manufacturing process of the display device 10 is further suppressed. Therefore, in the present embodiment, it is possible to provide the display device 10 with less defects and suppressed deterioration.

### Second Embodiment

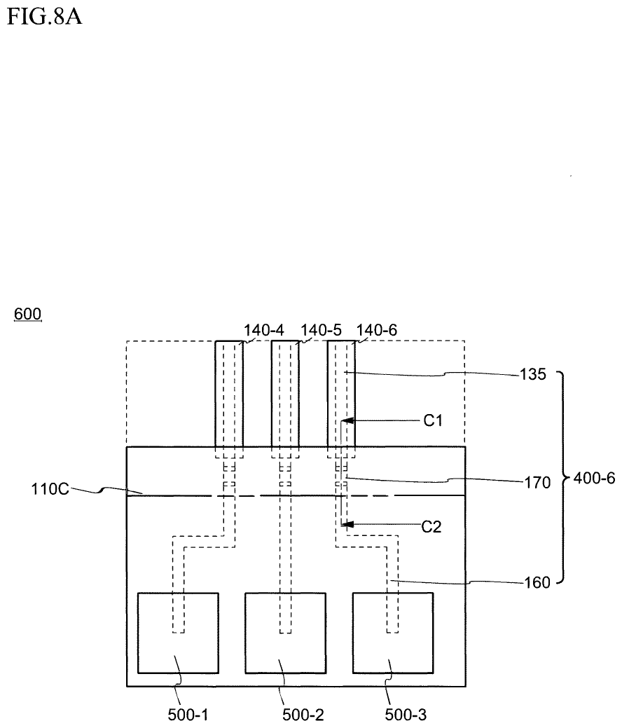

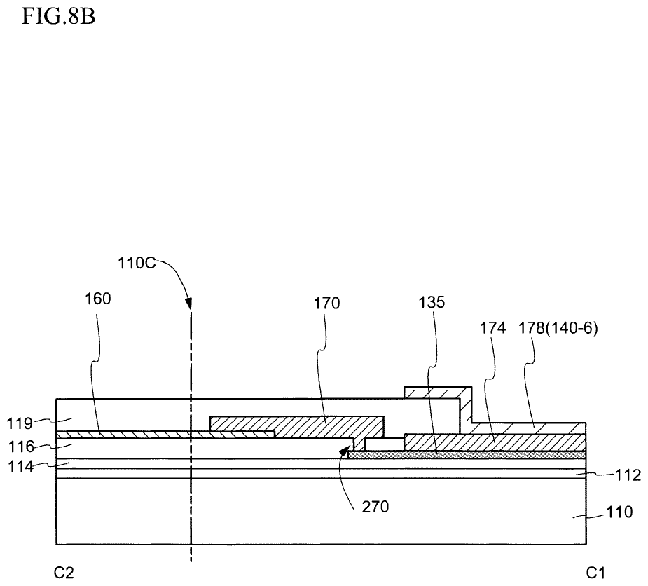

Next, a second embodiment of the present invention will be described with reference to FIG. 8 to FIG. 10.

### 1. Configuration of Display Device During Manufacturing

FIG. 8A is a top view showing a terminal of a display device and its periphery during the manufacturing of a display device according to an embodiment of the present invention. FIG. 8B is an end view showing a terminal of a display device and its periphery during the manufacturing of a display device according to an embodiment of the present invention. Specifically, FIG. 8B corresponds to an end view showing a cross-section taken along the line C1-C2 of FIG. 8A.

A difference from the display device during the manufacturing of the display device 10 shown in FIG. 4 to FIG. 7B is that the transistor arranged in the display part 120 has the bottom-gate structure. In addition, descriptions of the same or similar configurations as the display device 10 or the display device during the manufacturing of the display device 10 shown in FIG. 1 to FIG. 7B may be omitted.

FIG. 8A and FIG. 8B show the partial structure 600 of the display device during the manufacturing of the display device in which the liquid crystal element 309 is mounted.

As shown in FIG. 8A and FIG. 8B, an insulating layer 136 is formed above the insulating layer 114 and the wiring 135. The insulating layer 116 may partially expose the wiring 135 so that it can be directly connected to the terminal 140-6, as shown in FIG. 8B. The insulating layer 116 may be formed in the same process as the insulating layer 116 of the transistor having the bottom-gate structure. The same material as the insulating layer 118 can be used for the insulating layer 116. In addition, the wiring 135 can be formed in the same process as the gate electrode of the transistor arranged in the display part 120.

The wiring 160 is arranged above the insulating layer 116.

The wiring 170 is formed so as to be in direct contact with the wiring 160. The wiring 170 is formed above the insulating layer 136. An opening 270 reaching the wiring 135 is formed in the insulating layer 116, and the wiring 170 is connected to the wiring 135 via the opening 270. A wiring 174 formed simultaneously with the wiring 170 is formed above the wiring 135 exposed from the insulating layer 116.

Next, an insulating layer 119 is formed above the wiring 160, the wiring 170, the wiring 174, and the insulating layer 116. The material used for the insulating layer 118 and the insulating layer 132 can be used for the insulating layer 119. The insulating layer 119 may have a single-layer structure or a stacked structure. However, in the case where the insulating layer 119 has a single-layer structure, an inorganic insulating material such as silicon nitride (SiNₓ) formed by a CVD (Chemical Vapor Deposition) method may be used for the insulating layer 119. In addition, in the case where the insulating layer 119 is a stacked structure, an inorganic insulating material such as silicon nitride (SiNₓ) described above may be used for the layer in contact with the wiring 160. Forming the insulating layer 119 in direct contact with the wiring 160 reduces the resistance of the wiring 160 formed with the same composition as the oxide semiconductor layer of the transistor, and the wiring 160 can be the oxide conductive layer.

Next, a wiring 178 is formed above the wiring 174 and the insulating layer 119. The wiring 178 can be formed in the same step as the forming step of the common electrode of the liquid crystal element 309. In addition, since a conductive indium-tin oxide (ITO), indium-zinc oxide (IZO), zinc oxide (ZnO), or indium-tin-zinc oxide (ITZO) or other transparent conductive films of a translucent oxide that can ensure the visibility of a displayed image is used for the wiring 178, even if the wiring 178 is exposed, the terminal 140-6 can be suppressed from being corroded.

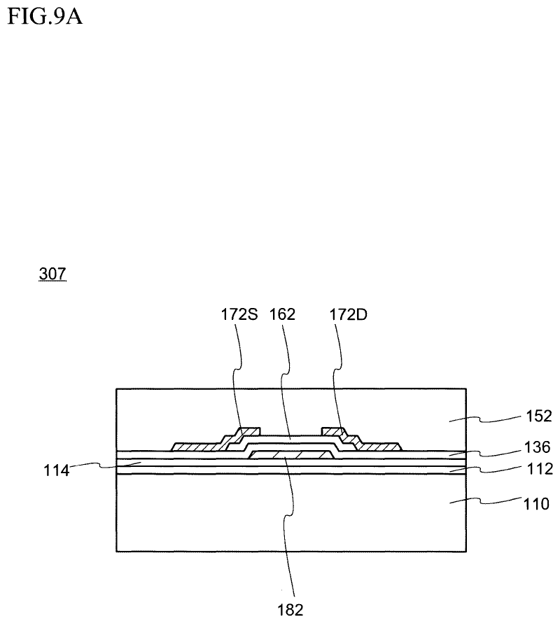

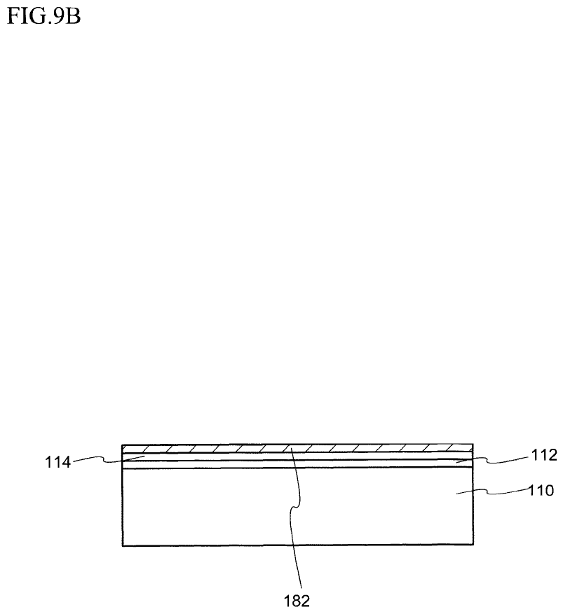

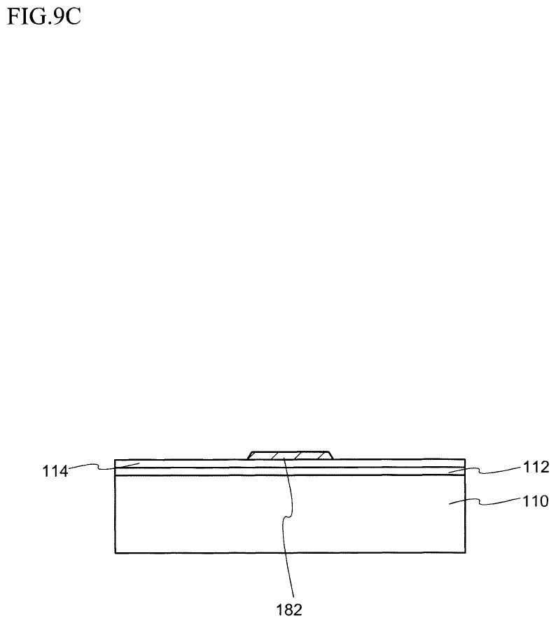

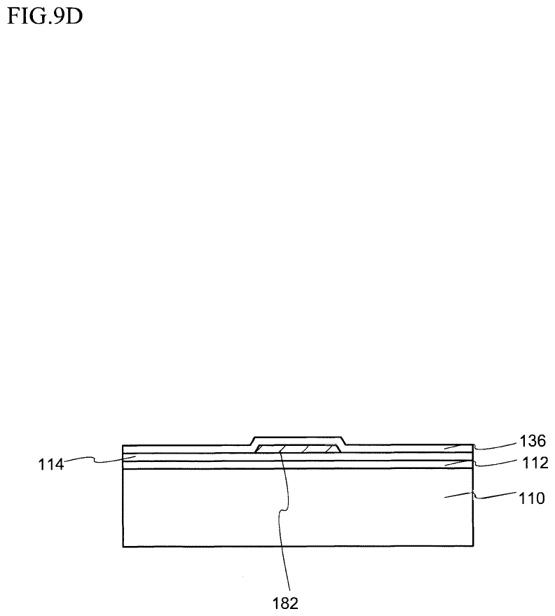

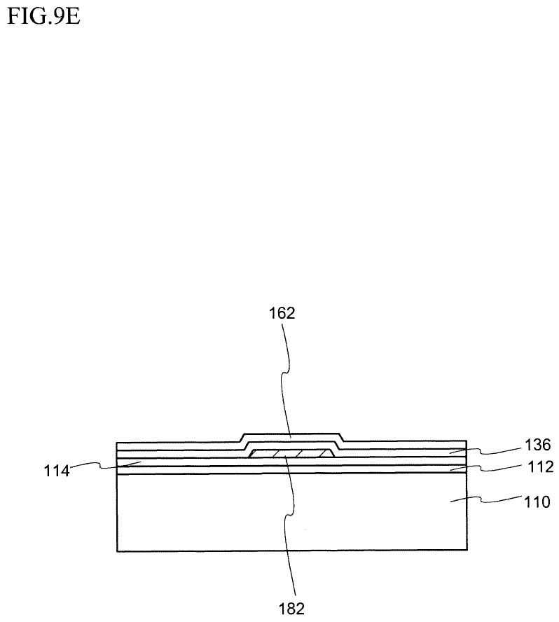

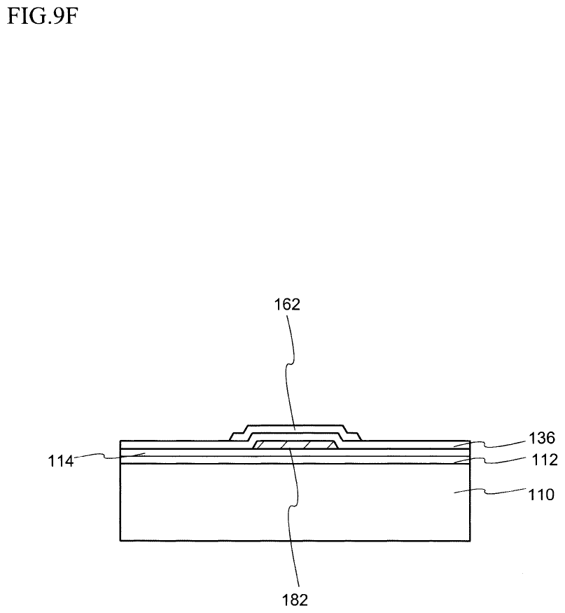

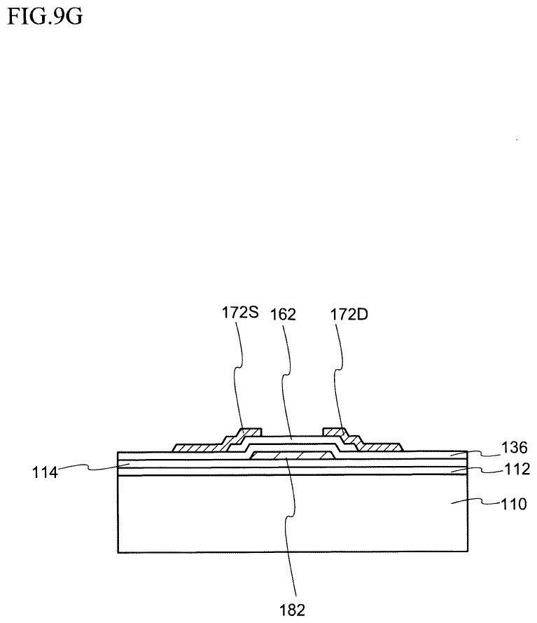

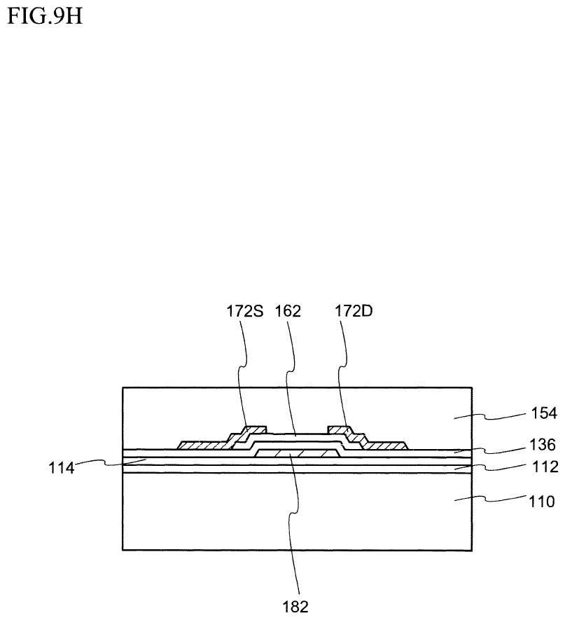

In this case, an example of the method for manufacturing the transistor arranged in the display part 120 will be described with reference to FIG. 9B to FIG. 9H. FIG. 9B to FIG. 9H are diagrams illustrating a method for manufacturing a display device according to an embodiment of the present invention. For example, the method for manufacturing the transistor shown in FIG. 9B to FIG. 9H relates to the transistor 307 having the bottom-gate structure shown in FIG. 9A.

### 2. Method for Manufacturing Display Device

FIG. 9A is an end view showing a configuration of a display device according to an embodiment of the present invention. The bottom-gate structure is often used for a transistor in which a liquid crystal element is arranged in a display device. Therefore, the transistor shown in FIG. 9A is, for example, the transistor 307 shown in FIG. 2B.

As shown in FIG. 9A, the transistor 307 includes the gate electrode 182, the insulating layer 136, the oxide semiconductor layer 162, the source electrode 172S, and the drain electrode 172D above the insulating layer 114.

Next, a method for manufacturing the transistor 307 will be described.

As shown in FIG. 9B, the gate electrode 182 is formed above the insulating layer 114. The gate electrode 182 is patterned as shown in FIG. 9C.

Next, the insulating layer 136 is formed above the gate electrode 182 and the insulating layer 114.

Next, as shown in FIG. 9E and FIG. 9F, the oxide semiconductor layer 162 is formed above the insulating layer 136 so as to overlap the gate electrode 182.

The source electrode 172S and the drain electrode 172D are formed in contact with the oxide semiconductor layer 162 as shown in FIG. 9G.

Next, the insulating layer 152 is formed above the oxide semiconductor layer 162, the source electrode 172S, and the drain electrode 172D, and an insulating layer 154 using a material different from the insulating layer 152 formed above the wiring 160 is formed. The insulating layer 154 may have a single-layer structure or a stacked structure. The same material as the insulating layer 136 may be used for the layer in contact with the oxide semiconductor layer 162.

### 3. Modification of Display Device During Manufacturing

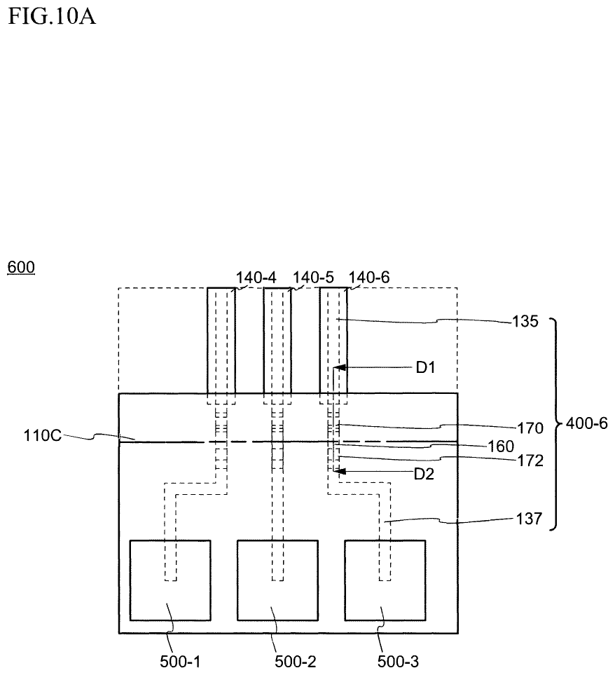

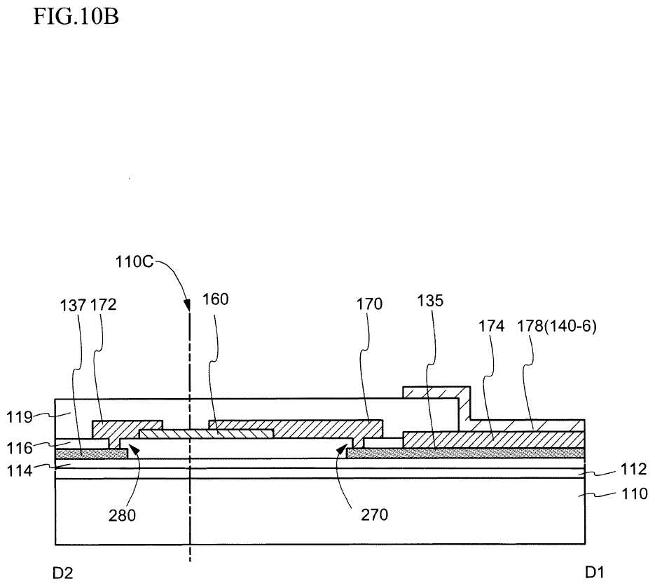

A modification of a display device during the manufacturing of the display device 10 will be described with reference to FIG. 10A and FIG. 10B. FIG. 10A is a top view showing a terminal of a display device and its periphery during the manufacturing of a display device according to an embodiment of the present invention. FIG. 10B is an end view showing a terminal of a display device and its periphery during the manufacturing of a display device according to an embodiment of the present invention. Specifically, FIG. 10B corresponds to an end view showing a cross-section taken along the line D1-D2 of FIG. 10A.

A difference from the display device during manufacturing the display device 10 shown in FIG. 8A and FIG. 8B is that the wiring 160, which is an oxide conductive layer, is used only for the wiring that bridges the cutline 110C, and a wiring using metal is used for the wiring that connects the wiring 160 and the test pad 500. In addition, descriptions of the same or similar configuration as the display device 10 or the display device during manufacturing shown in FIG. 1 to FIG. 9H may be omitted.

FIG. 10A and FIG. 10B show the partial structure 600 shown in FIG. 4. As shown in FIG. 10A and in FIG. 10B, the wiring 172 is connected in contact with the wiring 160 bridging the cutline 110C. The wiring 137 is connected to the wiring 172 and is connected to the wiring 137 via an opening 280. In addition, the wiring 137 is connected to the test pad 500-3.

### 4. Second Modification of Display Device During Manufacturing

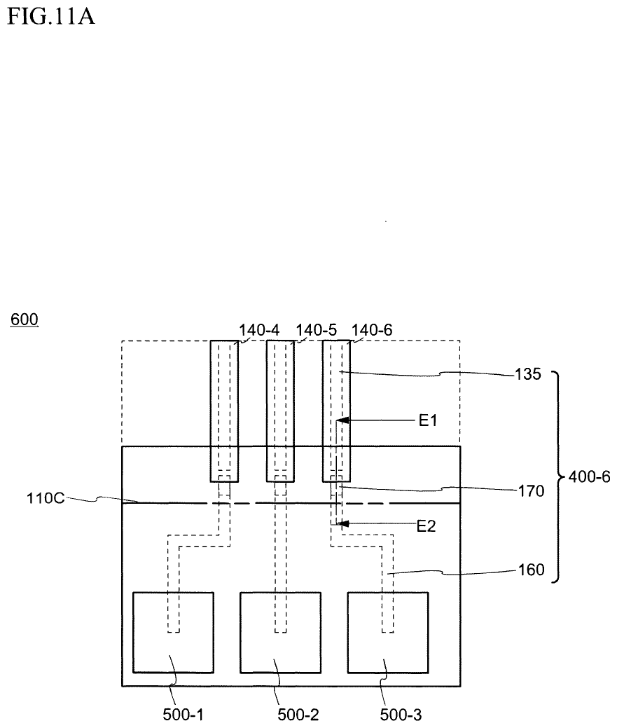

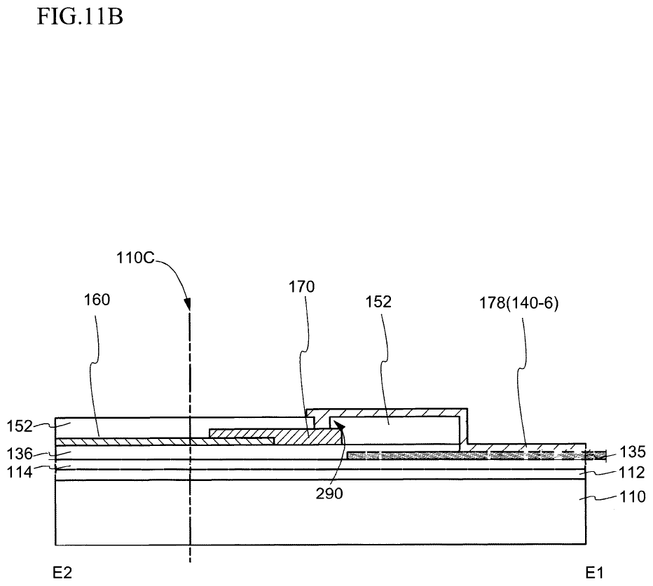

A modification of a display device during the manufacturing of the display device 10 will be described with reference to FIG. 11A and FIG. 11B. FIG. 11A is a top view showing a terminal of a display device and its periphery during the manufacturing of a display device according to an embodiment of the present invention. FIG. 11B is an end view showing a terminal of a display device and its periphery during the manufacturing of a display device according to an embodiment of the present invention. Specifically, FIG. 11B corresponds to an end view showing a cross-section taken along the line E1-E2 of FIG. 11A.

A difference from the display device during manufacturing the display device 10 shown in FIG. 8A and FIG. 8B is that the scanning line driving circuit 126 is not arranged, the same material is used for the insulating layer 136 and the insulating layer 152, and the wiring 178 and the wiring 135 are formed in contact with each other. In addition, descriptions of the same or similar configuration as the display device 10 or the display device during manufacturing shown in FIG. 1 to FIG. 10B may be omitted.

FIG. 11A and FIG. 11B show the partial structure 600 shown in FIG. 4. As shown in the FIG. 11A and FIG. 11B, the wiring 178 is formed on the wiring 135 exposed from the insulating layer 152 and the insulating layer 152. In addition, the wiring 178 is formed to be connected to the wiring 170 via the opening 290 reaching the wiring 170.

### 5. Third Modification of Display Device During Manufacturing

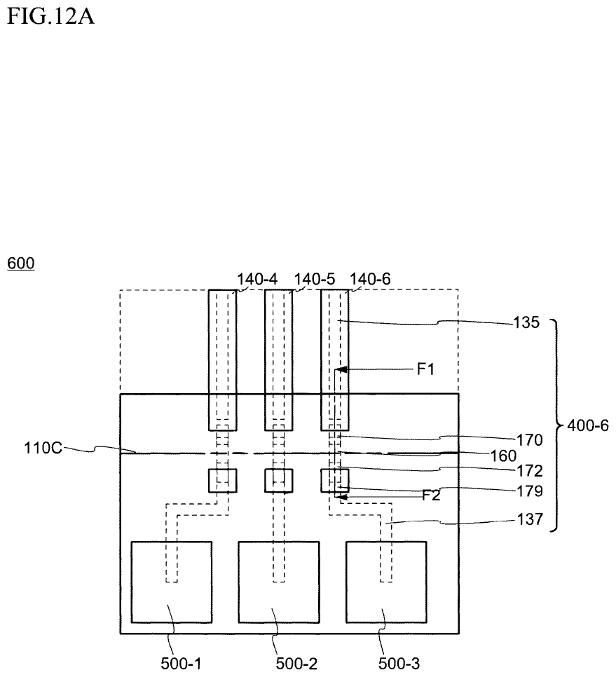

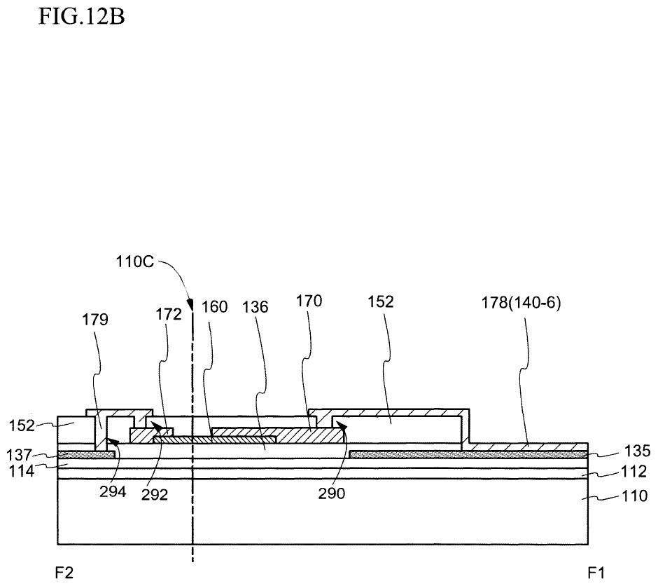

A modification of a display device during the manufacturing of the display device 10 will be described with reference to FIG. 12A and FIG. 12B. FIG. 12A is a top view showing a terminal of a display device and its periphery during the manufacturing of a display device according to an embodiment of the present invention. FIG. 12B is an end view showing a terminal of a display device and its periphery during the manufacturing of a display device according to an embodiment of the present invention. Specifically, FIG. 12B corresponds to an end view showing a cross-section taken along the line F1-F2 of FIG. 12A.

A difference from the display device 10 shown in FIG. 12A and FIG. 12B is that the wiring 160, which is an oxide conductive layer, is used only for the wiring that bridges the cutline 110C, and a wiring using metal is used for the wiring that connects the wiring 160 and the test pad 500. In addition, descriptions of the same or similar configuration as the display device 10 or the display device during manufacturing shown in FIG. 1 to FIG. 11B may be omitted.

FIG. 12A and FIG. 12B show the partial structure 600 shown in FIG. 4. As shown in FIG. 12A and FIG. 12B, the wiring 172 connects to the wiring 160 bridging the cutline 110C. A wiring 179 is connected to the wiring 172 via an opening 292, and is connected to the wiring 137 via an opening 294. The wiring 137 is connected to the test pad 500-3.

Each of the embodiments described above as the embodiment of the present invention can be appropriately combined as long no contradiction is caused. In addition, the addition, deletion, or design change of components, or the addition, deletion, or condition change of process as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a substrate;
a display part including a plurality of pixels, each of which includes a transistor having an oxide semiconductor layer on the substrate;
a first wiring electrically connected to the plurality of pixels;
a terminal electrically connected to the first wiring; and
a second wiring which is an oxide conductive layer having the same composition as the oxide semiconductor layer, has a cross-sectional surface along a periphery of the substrate, and is electrically connected to the terminal.

2. The display device according to claim 1, wherein
the oxide semiconductor layer includes a channel region, a source region and a drain region which sandwiches the channel region, and
the oxide conductive layer contains the same impurity element as the source region and the drain region.

3. The display device according to claim 1, further comprising:
a third wiring electrically connecting the second wiring and the first wiring; and
an insulating layer between the second wiring and the third wiring.

4. The display device according to claim 1, further comprising:
a fourth wiring on the same layer as the first wiring; and
a fifth wiring on the same layer as the third wiring and electrically connecting the second wiring and the fourth wiring.

5. The display device according to claim 1, further comprising:
a sixth wiring electrically connected to the second wiring and directly connecting the first wiring and the second wiring.

6. The display device according to claim 1, further comprising:
a seventh wiring on the same layer as the first wiring; and
an eighth wiring on the same layer as the sixth wiring and electrically connected to the second wiring via the seventh wiring.

7. A method for manufacturing a display device, the method comprising steps of:
forming an oxide semiconductor layer of a transistor arranged in each of a plurality of pixels constituting a display part on a substrate, and a first wiring which is an oxide conductive layer having the same composition as the oxide semiconductor layer;
forming a first insulating layer over the oxide semiconductor layer and the first wiring;
forming a gate electrode of the transistor and a second wiring electrically connected to the first wiring over the first insulating layer;
forming a second insulating layer over the gate electrode and the second wiring;
forming a plurality of first openings reaching the first wiring and second openings reaching the second wiring in the second insulating layer;
forming a third wiring electrically connected to the second wiring over the second insulating layer and in the plurality of first openings and the plurality of second openings;
forming a third insulating layer over the third wiring;
forming a test pad and a terminal electrically connected to the second wiring on the third insulating layer; and
cutting the substrate so that the first wiring is divided.

8. The method according to claim 7, wherein
a source region and a drain region that sandwich a channel region in the oxide semiconductor layer and the first wiring are doped with an impurity after forming the gate electrode.

9. The method according to claim 8, wherein
the oxide semiconductor layer includes the channel region and the source region and the drain region that sandwich the channel region,
the oxide conductive layer contains the same impurity element as the impurity contained in the source region and the drain region.

10. The method according to claim 7, further comprising steps of:
before forming the oxide semiconductor layer and the first wiring, forming the fourth wiring over the substrate; and
forming a fourth insulating layer over the fourth wiring.

11. A method for manufacturing a display device, the method comprising steps of:
forming a first wiring and a gate electrode of a transistor arranged in each of a plurality of pixels constituting a display part on a substrate;
forming a first insulating layer over the first wiring and the gate electrode;
forming an oxide semiconductor layer of the transistor over the first insulating layer and a second wiring which is an oxide conductive layer having the same composition as the oxide semiconductor layer and electrically connected to the first wiring;
forming a plurality of openings reaching the first wiring in the first insulating layer;
forming a third wiring over the second wiring and in the plurality of openings;
forming a second insulating layer over the third wiring;
forming a test pad and a terminal electrically connected to the first wiring over the second insulating layer; and
cutting the substrate so that the second wiring is divided.

12. The method according to claim 11, further comprising:
forming a fourth wiring in the same layer as the first wiring; and
forming a fifth wiring electrically connected to the second wiring via the fourth wiring in the same layer as the third wiring.

13. The method according to claim 11, wherein
the second wiring is an oxide conductive layer having the same composition as the oxide semiconductor layer.

14. The method according to claim 13, wherein
the second insulating layer contains silicon nitride and is formed in contact with the second wiring.
